(19) United States
(12) Patent Application Publication
(10) Pub. No.: US 2007/0076372 A1
(43) Pub. Date: Apr. 5, 2007

(54) METHOD AND APPARATUS FOR CONTROLLING ROTATION SPEED OF FAN

(75) Inventor: WEN-HSIANG LIN, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,125

(22) Filed: Jun. 24, 2006

(30) Foreign Application Priority Data
Aug. 19, 2005 (CN) 200510036747.3

(51) Int. Cl. H05K 7/20

(52) U.S. Cl. 361/695

(57) ABSTRACT

A method and an apparatus for automatically controlling rotation speed of a cooling fan are provided. The method includes the following steps: Sampling temperature values of the electronic component at Time (n−1) and at Time (n). Then storing the temperature values at Time (n−1) and at Time (n). Then comparing the temperature vale at Time (n−1) with that at Time (n). And then setting the rotation speed of the cooling fan according to the comparison result in the last step. The present invention can not only automatically control the rotation speed of a cooling fan, but also reduce the noise of the cooling fan.

### FIELD OF THE INVENTION

The present invention relates to a method and an apparatus for controlling operation/rotation speed of a fan, and particularly to a method and an apparatus for automatically controlling the operation (rotation) speed of a CPU cooling fan.

### DESCRIPTION OF RELATED ART

Generally, a computer system includes a motherboard with various chips such as a central processing unit (CPU) mounted thereon, a storage device such as a hard disc, and input/output devices, each of which is known to generate heat when operated in a computer system. Especially, the CPU produces a large amount of heat. If the heat generated from the CPU is not dissipated in a timely fashion, it may damage the CPU or even the computer system. Developments in today's highly information-intensive society have led to remarkable improvements in performances of electronic devices. A cooling fan is used to facilitate removal of heat to keep a temperature of the CPU within a safe temperature range. In general, the faster the fan rotates/runs, the more efficient heat dissipation will be. However, high rotation speeds of the cooling fan will produce a lot of noise.

eferring to FIG. 5, a relation between a temperature of the CPU and the rotation speed of the cooling fan according to a conventional method is shown. X-axis shows the temperature of the CPU, and Y-axis shows the power of the cooling fan. Tambient is a value of the temperature of the CPU when the cooling fan begins to work, Tcontrol is a value of the temperature of the CPU when the cooling fan rotates steadily, and Tcasemax is a maximum temperature of the CPU permitted by a CPU Thermal Profile. “Min” is a value of the minimum power determined by a start up voltage of the cooling fan and “Max” is a value of the maximum power when the cooling fan rotates at full speed. A curve 10 shows the power change of the cooling fan as the CPU temperature changes. The slope of the curve 10 between the T ambient and the T control is K10. As shown from this graph, the conventional method regulates the rotation speed of the cooling fan in three stages. After the cooling fan rotates steadily, the power of the cooling fan remains unchanged. That is to say, the rotation speed of the cooling fan is not regulated once the cooling fan is up to speed.

IG. 6 is a graph of the temperature change of the CPU according to the conventional method, contrasted with that according to the thermal profile. A curve 200 shows the temperature change of the CPU according to the CPU thermal profile. A curve 20 shows the temperature change of the CPU according to the conventional method. As shown FIG. 6, the temperature of the CPU meets with the CPU thermal profile, but the power of the cooling fan is wasted and may lead to a lot of noise.

What is needed is a method for automatically controlling the rotation speed of the cooling fan to conserve power while still meeting the demands of the thermal profile.

### SUMMARY OF THE INVENTION

A method and an apparatus for automatically controlling rotation/operation speed of a cooling fan are provided. In a preferred embodiment, the method includes the following steps: Sampling temperature values of the electronic component at Time (n−1) and at Time (n). Then storing those temperature values. Then comparing the temperature value Time (n−1) with Time (n). And then setting the rotation speed of the cooling fan according to the comparison result. The present invention can not only automatically control the rotation speed of a cooling fan, but also reduce the noise of the cooling fan during those times when maximum cooling is not needed.

Other objects, advantages and novel features will become more apparent from the following detailed description when taken in conjunction with the accompanying drawings, in which:

### BRIEF DESCRIPTION OF THE DRAWINGS

FIG. 1 is a schematic diagram of an apparatus for controlling the rotation speed of a fan, in accordance with a preferred embodiment of the present invention;

FIG. 2 is a graph showing a relation between a temperature of a CPU and the rotation speed of the cooling fan according to the present invention;

FIG. 3 is a flow chart of a method for controlling rotation speed of a cooling fan, in accordance with a preferred embodiment of the present invention;

FIG. 4 is a graph of the temperature change of the CPU according to the present invention, contrasted with that according to a thermal profile;

FIG. 5 is a graph showing a relation between a temperature of a CPU and rotation speed of the cooling fan according to a conventional method; and

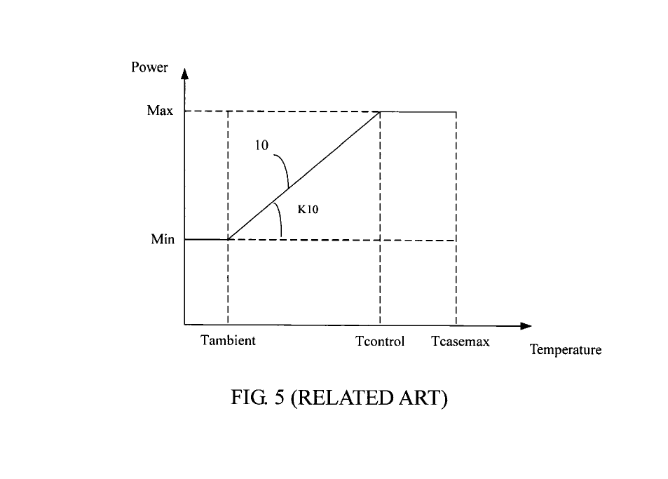

FIG. 6 is a graph of the temperature change of the CPU according to the conventional method, contrasted with that according to the thermal profile.

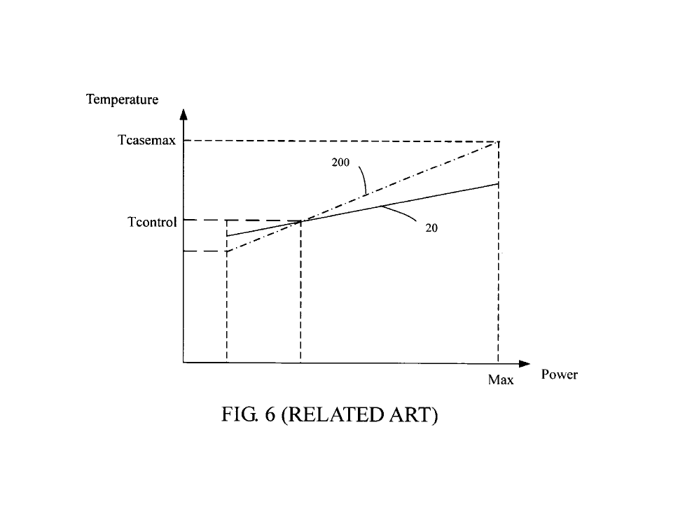

### DETAILED DESCRIPTION OF THE INVENTION

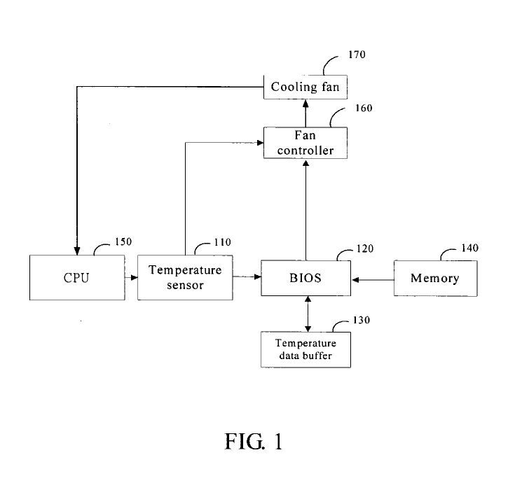

Referring to FIG. 1, a schematic diagram of an apparatus for controlling the rotation/operation speed of a cooling fan 170, in accordance with a preferred embodiment of the present invention is shown. The apparatus includes a temperature sensor 110. The temperature sensor 110 is used to detect temperatures of an electronic component, such as a CPU 150, that is the object to be cooled by the cooling fan 170. The temperature values are input to a basic input output system (BIOS) 120 and stored in a temperature data buffer 130. In the BIOS 120, interruptions are generated by a system management interruption (SMI). The SMI is triggered by the temperature value from the temperature sensor 110. In the BIOS 120, a control program is stored for determining how much power should be supplied to the cooling fan 170 according to the magnitude of the rate of change of the temperature of the CPU 150. The control program is executed when the SMI is triggered. A number of slopes are predetermined and stored in the memory 140. Each slope represents how much power to be supplied to the cooling fan 170 for a given temperature of the CPU 150. The control program selects the corresponding slope from the memory 140 according to the temperature change of the CPU 150 and then the BIOS 120 outputs a control signal to the fan controller 160. The fan controller 160 regulates the rotation speed of the cooling fan 170. Further details will be described later.

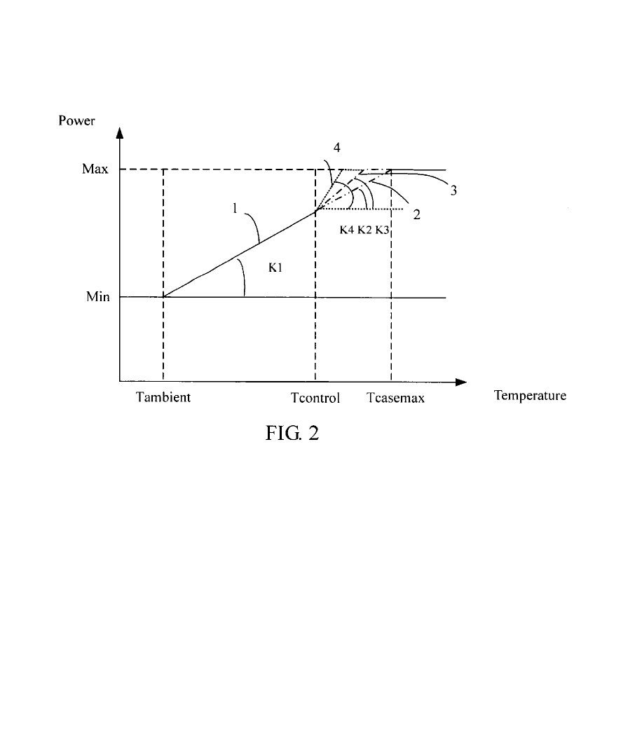

FIG. 2 is a graph showing a relation between a temperature of a CPU 150 and power used by the cooling fan 170 according to the present invention. X-axis shows the temperature of the CPU 150, and Y-axis shows the power used by the cooling fan 170. Tambient is the temperature of the CPU 150 when the cooling fan 170 begins to work, Tcontrol is the temperature of the CPU 150 when the cooling fan 170 rotates at a steady rate, and Tcasemax is the maximum temperature of the CPU 150 permitted by a CPU thermal profile. “Min” is a value of the minimum power determined by a start up voltage of the cooling fan 170 and “Max” is a value of the maximum power used when the cooling fan 170 rotates at a full speed. A curve 1 shows the power change of the cooling fan 170 between the T ambient and T control points. The slope (rate of change or rate of power output to the fan 170) of a curve 1 is represented by K1. Curves 2, 3, and 4 are between the T control and the T casemax points and have different slopes K2, K3, and K4. The curves 2, 3, and 4 are examples of possible curves from which one is selected according to the magnitude of the rate of change of the temperature of the CPU 150. When the temperature of the CPU 150 changes from T control to T casemax, the curve corresponding to the rate of change will be selected to control the amount of power supplied to the cooling fan 170. In this way enough power is supplied to the fan 170 by the controller 160 to efficiently provide a sufficient cooling effect.

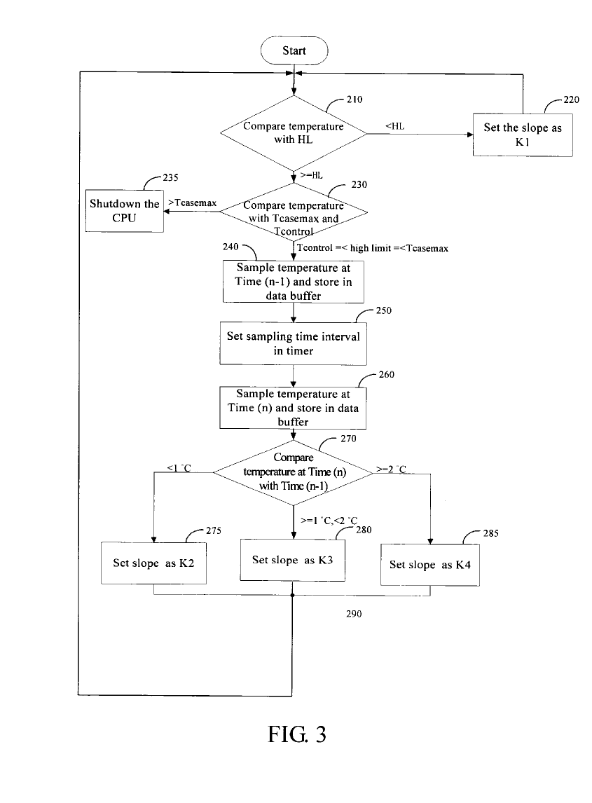

Referring to FIG. 3, a method for automatically controlling the rotation/operation speed of the cooling fan 170, in accordance with a preferred embodiment of the present invention is shown. The control program starts to be executed as the cooling fan 170 begins to work. A method for determining how much power should be supplied to the cooling fan 170 includes the following steps.

Step 210: A high limit (HL) are predetermined in the control program to trigger the SMI. An initial value of the HL is set as the Tcontrol. The temperature detected by the temperature sensor 110 is input to the BIOS 120 and compared with the HL, in order to determine if the temperature is above or below a predetermined range to trigger the SMI.

Step 220: If the temperature is lower than the value of the HL, then the BIOS 120 uses the slope K1 stored in the memory 140. That is to say, the temperature value of the CPU 150 is lower than the Tcontrol, so the power supplied to the cooling fan 170 may be small. And then, the program returns to the step 210 to compare the temperature with the HL until the temperature value is higher than the Tcontrol.

tep 230: If the temperature value is higher than or equal to the value of the HL, the SMI is triggered. Then the temperature value is compared with the Tcasemax and the Tcontrol. Now the power supplied to the cooling fan 170 should be regulated or the cooling fan 170 should be shut down.

tep 235: If the temperature value is higher than the Tcasemax, it indicates the temperature of the CPU 150 exceeds the maximum temperature permitted by the CPU thermal profile. So the CPU 150 is shut down.

tep 240: If the temperature value is lower than the Tcasemax, sampling the temperature at the Time (n−1). The value of the temperature at Time (n−1) is stored in the temperature data buffer 130.

tep 250: Setting a temperature-sampling time interval in the timer.

tep 260: Sampling another temperature value at the next time Time (n) and the value of the temperature at Time (n) is stored in the temperature data buffer 130.

tep 270: Comparing the temperature value sampled at Time (n−1) with that at Time (n) to calculate a change rate of temperature in the preset unit time interval, i.e., Time (1).

tep 275: If the difference between them (the change rate of temperature) is less than 1° C., the value of the slope is set as K2. The value of the K2 slope is more than K1. The temperature now is more than the Tcontrol, so more power needs to be supplied to the cooling fan 170.

tep 280: If the difference (the change rate of temperature) is less than 2° C. and more than or equal to 1° C., the value of the slope is set as K3. The value of the K3 slope is more than K2. The power supplied to the cooling fan 170 is more than in the step 275, for a faster rate of change of the temperature.

tep 285: If the difference (the change rate of temperature) is more than or equal to 2° C., the value of the slope is set as K4. The value of the K4 slope is more than K3. The power supplied to the cooling fan 170 is more than in the step 280, for a faster rate of change of the temperature.

hen, the program will return to the step 210 and compare the temperature with the HL, in order to automatically regulate the rotation speed of the cooling fan 170 according to the change of the temperature of the CPU 150.

herefore, the fan controller 160 is controlled to regulate the rotation speed of the cooling fan 170 by use of the control signal from the control program. And then, the rotation speed of the cooling fan 170 will be controlled by a fixed slope, unless the temperature of the CPU 150 drops to a lower temperature.

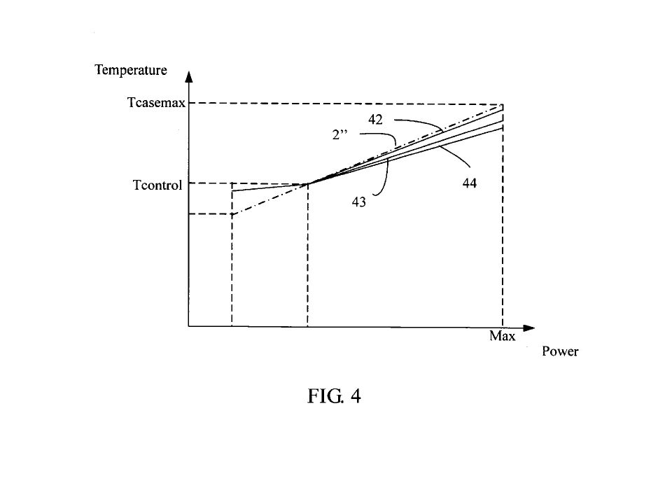

Referring to FIG. 4, a graph of the temperature of the CPU 150 according to the present invention is shown, contrasted with a graph of the temperature of the CPU 150 according to a CPU thermal profile. X-axis shows power of the cooling fan 170, and Y-axis shows temperature of the CPU 150. A curve 20′ indicates the temperature change of the CPU 150 according to the CPU thermal profile. Curves 42, 43, and 44 indicate the temperature changes of the CPU 150 under the slope K2, K3, and K4 respectively. The curves 42, 43, and 44 are selected according to the requirement of a CPU thermal profile. As shown in this diagram, the temperatures of the CPU 150 meet with the CPU thermal profile, and the overall output power of the cooling fan 170 reduced thus saving energy. Furthermore, the noise caused by the cooling fan 170 is reduced. In addition, the CPU 150 can be automatically shut down when the temperature exceeds the permitted maximum value. So, the present invention can automatically control the rotation speed of a CPU cooling fan and reduce the noise of the cooling fan.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment.

What is claimed is:

1. An apparatus for controlling the rotation speed of a cooling fan of an electronic component, the apparatus comprising:
a temperature sensor for detecting temperatures of the electronic component in a time interval;
a storing unit for storing the temperature values detected by the temperature sensor;
a fan controller for controlling the rotation speed of the cooling fan; and a control unit having a control program, the control program comparing the temperature values in a time interval, then determining how much power to be supplied to the cooling fan, and outputting a control signal to the fan controller according to a comparison result.

2. The apparatus as claimed in claim 1, wherein the storing unit is a temperature data buffer.

3. The apparatus as claimed in claim 1, wherein the control program is executed when a system management interruption (SMI) is triggered, and the SMI is stored in a basic input output system (BIOS).

4. The apparatus as claimed in claim 3, further comprising a memory for storing a plurality of ratios of powers of the cooling fan to the temperatures of the electronic component, the control program uses the corresponding ratio to control the fan controller regulating the rotation speed of the cooling fan, according to the comparison result, wherein the ratios are determined according to a magnitude of a rate of change in the temperature.

5. The apparatus as claimed in claim 1, wherein the time interval is determined by a timer.

6. A method for controlling a rotation speed of a cooling fan of an electronic component, the method comprising steps of:
Sampling temperature values of the electronic component at Time (n−1) and at Time (n); then
Storing the temperature values at Time (n−1) and at Time (n); then
Comparing the temperature value sampled at Time (n−1) with that at Time (n); and then
Setting the rotation speed of the cooling fan according to the comparison result in the last step.

7. The method as claimed in claim 6, before the step of sampling the temperature further comprising: Predetermining a high limit (HL) in a system management interruption (SMI), and comparing the temperature value at Time (n−1) with the value of the HL, to judge whether the temperature is higher than the HL.

8. The method as claimed in claim 7, wherein if the temperature value is lower than the HL, then a first slope is set to regulate the rotation speed of the cooling fan.

9. The method as claimed in claim 8, wherein if the temperature value is higher than or equal to the value of the HL, then the temperature value is compared with a maximum temperature value T casemax and another temperature value T control.

10. The method as claimed in claim 9, wherein if the temperature value is higher than the T casemax, it indicates the temperature exceeds the permitted maximum temperature, and the electronic component is shut down.

11. The method as claimed in claim 9, wherein if the temperature value is lower than the T casemax, sampling and storing the temperatures of the electronic component at Time (n−1) and at Time (n).

12. The method as claimed in claim 6, wherein the step of setting the rotation speed of the cooling fan comprises setting different slopes according to the comparison result.

13. A method for controlling an operation speed of a cooling fan for cooling an electronic component, the method comprising steps of:
sensing temperature of an electronic component;
storing values of said sensed temperature according to a preset way;
starting a cooling fan for cooling said electronic component when said sensed temperature of said electronic component is recognized as higher than a first threshold value;
setting a first rate of power output to said cooling fan for operation and cooling said electronic component after said cooling fan is started;
triggering control onto said cooling fan when said temperature is recognized as higher than a second threshold value larger than said first threshold value;
retrieving a change rate of said temperature by sampling said stored values of said sensed temperature; and
setting a second rate, higher than said first rate, of power output to said cooling fan for operation and cooling said electronic component based on said retrieved change rate of said temperature.

14. The method as claimed in claim 13, wherein said second rate of power output to said cooling fan for operation is set relatively higher when said retrieved change rate of said temperature is relatively higher.
